(19) United States
(12) Patent Application Publication
(10) Pub. No.: US 2021/0043567 A1
(43) Pub. Date: Feb. 11, 2021

(54) PLACE-AND-ROUTE RESISTANCE AND CAPACITANCE OPTIMIZATION USING MULTI-HEIGHT INTERCONNECT TRENCHES AND AIR GAP DIELECTRICS

(71) Applicant: Intel Corporation, Santa Clara, CA (US)

(72) Inventors: Mark ANDERS, Hillsboro, OR (US); Himanshu KAUL, Portland, OR (US); Ram KRISHNAMURTHY, Portland, OR (US); Kevin Lai LIN, Beaverton, OR (US); Mauro KOBRINSKY, Portland, OR (US)

(21) Appl. No.: 16/534,104

(22) Filed: Aug. 7, 2019

(51) Int. Cl. H01L 23/528; G06F 17/50; G11C 5/06

(52) U.S. Cl. CPC H01L 23/5286; G11C 5/063; G06F 17/5077; G06F 17/5072

(57) ABSTRACT

Embodiments disclosed herein include a semiconductor device with interconnects with non-uniform heights. In an embodiment, the semiconductor device comprises a semiconductor substrate, and a back end of line (BEOL) stack over the semiconductor substrate. In an embodiment, the BEOL stack comprises first interconnects and second interconnects in an interconnect layer of the BEOL stack. In an embodiment, the first interconnects have a first height and the second interconnects have a second height that is different than the first height.

### TECHNICAL FIELD

Embodiments of the present disclosure relate to semiconductor devices, and more particularly to automatic place-and-route (APR) optimization through the use of multi-height interconnect trenches and air gap dielectrics.

### BACKGROUND

In semiconductor dies, the signal paths between the transistor devices are made by interconnects. Depending on the complexity of the semiconductor die, there may be many interconnect layers. The resistance and capacitance are critical parameters that must be considered during the design of the signal paths. Resistance impacts the delay of a signal. For example, higher resistances have a longer delay. Capacitance impacts the power consumption and delay. For example, higher capacitance increases the power consumption and delay. Even though increasing the interconnect height decreases resistance, it also increases capacitance. Both affect delay, which is proportional to R*C. However, often the resistance decrease is more than the capacitance increase. Also, side-to-side spacing can be increased which decreases the largest component of the capacitance. Increasing either the width or side-to-side spacing increase the area occupied per signal.

In electrical paths that are timing critical, the delay must be minimized. As such, a low resistance path is desired. Since the height of the interconnects within a layer are uniform, the only way to selectively decrease resistance is to increase the width of the interconnect. However, this results in an area penalty. Additionally, since the heights of the interconnects within a layer are uniform, increasing the height of the interconnects globally to reduce resistance results in a significant increase in the capacitance. This reduces the power efficiency. An additional option may include moving the electrical path to a higher layer in the stack where interconnects are typically larger. However, the higher layers also have a larger pitch. This reduces the number of interconnects in higher layers, and it is not possible to move all timing critical electrical paths up to higher layers.

Accordingly, the routing path design must strike a balance between resistance and capacitance. The height of the interconnects may be increased to improve delay at the expense of power consumption, or the power consumption may be reduced at the expense of longer delays.

### BRIEF DESCRIPTION OF THE DRAWINGS

FIG. 1 is a graph of the capacitance versus resistance of interconnects in an interconnect layer, in accordance with an embodiment.

FIG. 2A is a cross-sectional illustration of an interconnect layer with first interconnects with a first height and second interconnects with a second height, in accordance with an embodiment.

FIG. 2B is a cross-sectional illustration of an interconnect layer with first interconnects with a first height, second interconnects with a second height, and third interconnects with a third height, in accordance with an embodiment.

FIG. 2C is a cross-sectional illustration of and interconnect layer with first interconnects and second interconnects that are surrounded by an air gap, in accordance with an embodiment.

FIG. 3A is a schematic view of a semiconductor die with a plurality of different processing blocks, in accordance with an embodiment.

FIG. 3B is a schematic view of one of the processing blocks that comprises a plurality of routing paths, in accordance with an embodiment.

FIG. 3C is a schematic view of one of the routing paths with a plurality of nets, in accordance with an embodiment.

FIG. 3D is a plan view illustration that includes a plurality of segments of one of the nets, in accordance with an embodiment.

FIG. 4 is a cross-sectional illustration of a semiconductor die with a back end of line (BEOL) stack that comprises interconnect layers with first interconnects and second interconnects, in accordance with an embodiment.

FIG. 5A is a schematic illustration of a signal net with a driving cell and a plurality of load cells that are electrically coupled by interconnects, in accordance with an embodiment.

FIG. 5B is a cross-sectional illustration that depicts a first interconnect proximate to the driving cell and a second interconnect proximate to one of the load cells, in accordance with an embodiment.

FIG. 6A is a block diagram of a semiconductor die with a processor block and a plurality of memory blocks, in accordance with an embodiment.

FIG. 6B is a circuit diagram of a memory block that is a register file, in accordance with an embodiment.

FIG. 6C is a circuit diagram of a memory block that is static random access memory (SRAM), in accordance with an embodiment.

FIG. 7 is a process flow diagram illustrating a process for determining whether a signal path should include first interconnects with a first height or second interconnects with a second height, in accordance with an embodiment.

FIG. 8 illustrates a computing device in accordance with one implementation of an embodiment of the disclosure.

FIG. 9 is an interposer implementing one or more embodiments of the disclosure.

### EMBODIMENTS OF THE PRESENT DISCLOSURE

Described herein are processes for automatic place-and-route (APR) optimization through the use of multi-height interconnect trenches and air gap dielectrics and the resulting structures, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

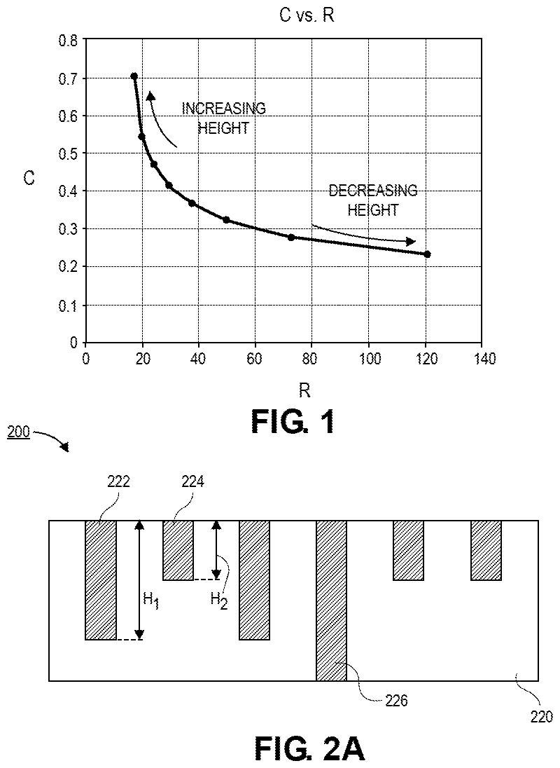

As noted above, decreasing the resistance of an interconnect results in an increase in the capacitance. Further, since existing interconnect layers only allow for interconnects of a single height, there is always a direct tradeoff between resistance and capacitance. This relationship is shown in the graph illustrated in FIG. 1. As shown, interconnects with increasing height have lower resistance but higher capacitance, whereas interconnects with decreasing height have lower capacitance, but higher resistance.

Accordingly, embodiments disclosed herein include interconnect layers that include multi-height interconnects. This allows for the signal paths to be optimized for a given performance parameter. For example, signal paths that are timing critical may be routed along interconnects with a larger height, and the remainder of the signal paths may be routed along interconnects with a smaller height. This allows for signal delay metrics to be met while still maintaining power efficiency. Furthermore, since the resistance is decreased by increasing the height of the interconnect, there is no area penalty (as is the case when the width of the interconnect is increased). That is, the width of timing critical signal paths may be substantially the same as all other signal paths within a metal layer. Furthermore, selecting taller height interconnects for timing critical signals improves the delay without needing to decrease signal density by moving a signal to a higher interconnect layer.

In addition to improving delay characteristics, reducing resistance by selecting a taller height interconnect also allows for longer distances between repeaters for improved power and lower cell area. Embodiments also allow for a reduction in the congestion and blockage of higher interconnect layers by allowing signals to be moved to lower layers with tall height interconnects. Additionally, for a signal that has one driver cell branching out to many load cells, an interconnect with non-uniform height can provide significant advantages. For example, tall interconnect segments proximate to the driver cell and short interconnect segments proximate to the load cells may provide improved performance.

Furthermore, the interconnect dimensions across multiple layers are often optimized for either CPU (aggressive scaling for performance) vs. SOC (minimal scaling for signal density). The availability of multi-height interconnects within a single layer can allow for both design optimizations within the same process. In some embodiments, air gap dielectrics may also be used to improve the resistance-capacitance (RC) characteristics and can yield similar optimization tradeoffs by lowering line-to-line capacitance for such interconnect layers.

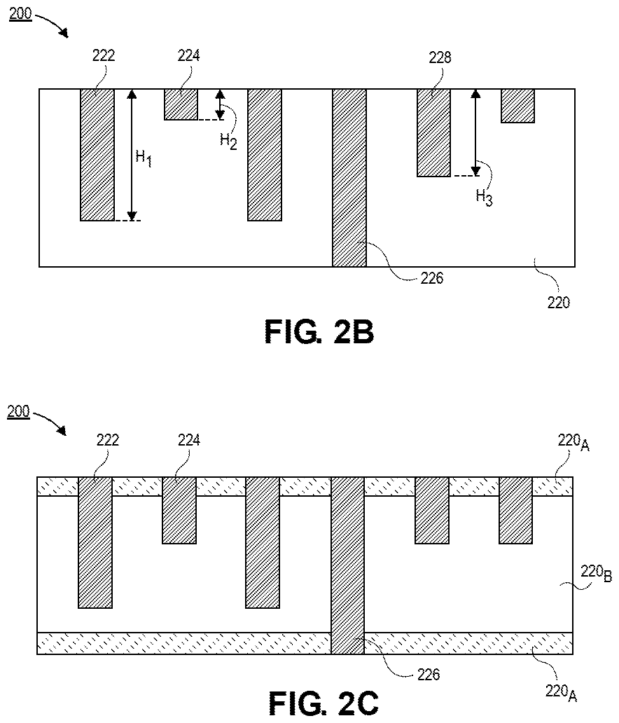

Referring now to FIG. 2A, a cross-sectional illustration of an interconnect layer 200 is shown, in accordance with an embodiment. In an embodiment, the interconnect layer 200 is one interconnect layer 200 in a stack of interconnect layers (e.g., a back end of line (BEOL) stack). The interconnect layer 200 may be the first layer over the front end of line (FEOL) portion of a semiconductor substrate, or any other layer of the BEOL stack. In some embodiments, the interconnect layer 200 may be referred to as a “metal layer” (e.g., metal layer 1 (M1), metal layer 2 (M2), etc.). In an embodiment, the BEOL stack may comprise any number of interconnect layers 200, depending on the complexity of the device.

In an embodiment, the interconnect layer 200 may comprise an interlayer dielectric (ILD) 220. In an embodiment, as used throughout the present description, ILD material is composed of or includes a layer of a dielectric or insulating material. Examples of suitable dielectric materials include, but are not limited to, oxides of silicon (e.g., silicon dioxide (SiO₂)), doped oxides of silicon, fluorinated oxides of silicon, carbon doped oxides of silicon, various low-k dielectric materials known in the arts, and combinations thereof. The interlayer dielectric material may be formed by techniques, such as, for example, chemical vapor deposition (CVD), physical vapor deposition (PVD), or by other deposition methods.

In an embodiment, the interconnect layer 200 may comprise a plurality of interconnects 222/224. In an embodiment, the first interconnects 222 may have a first height H₁ and the second interconnects 224 may have a second height H₂. In an embodiment, the first height H₁ is different than the second height H₂. For example, the first height H₁ is shown as being greater than the second height H₂. The larger height H₁ provides a lower resistance to the first interconnects 222 compared to the second interconnects 224. The smaller height H₂ provides a lower capacitance to the second interconnects 224 compared to the first interconnects 222. Accordingly, chip designers are free to optimize routing paths for both low power consumption and high performance (e.g., low signal delay).

In an embodiment, the first interconnects 222 and the second interconnects 224 may have top surfaces that are substantially coplanar with each other. For example, the top surfaces of the first interconnects 222 and the second interconnects 224 may both be substantially coplanar with a top surface of the ILD 220. Accordingly, due to the difference in heights H₁ and H₂, the bottom surfaces of the first interconnects 222 and the second interconnects 224 are located at different Z-heights within the ILD 220.

In an embodiment, the first interconnects 222 and the second interconnects 224 may have substantially uniform widths. Accordingly, the decrease in the resistance of the first interconnects 222 does not come at the cost of an area penalty, as is the case described above. Accordingly, fine pitch high density interconnects may still be maintained even at lower interconnect layers (e.g., M1, M2, etc.).

In an embodiment, the interconnect layer 200 may also include one or more vias 226. The vias 226 may pass through to the bottom of the interconnect layer 200. It is to be appreciated that the vias 226 may be connected to bottom surfaces of either first interconnects 222 or second interconnects 224. That is, the vias 226 may also have a non-uniform height within an interconnect layer 200. For example, a via 226 attached to a first interconnect 222 may be shorter than a via 226 attached to a second interconnect 224.

In an embodiment, as is also used throughout the present description, metal lines or interconnect line material (and via material) are composed of one or more metal or other conductive structures. A common example is the use of copper lines and structures that may or may not include barrier layers between the copper and surrounding ILD material. As used herein, the term metal includes alloys, stacks, and other combinations of multiple metals. For example, the metal interconnect lines may include barrier layers (e.g., layers including one or more of Ta, TaN, Ti or TiN), stacks of different metals or alloys, etc. Thus, the interconnect lines may be a single material layer, or may be formed from several layers, including conductive liner layers and fill layers. Any suitable deposition process, such as electroplating, chemical vapor deposition or physical vapor deposition, may be used to form interconnect lines. In an embodiment, the interconnect lines are composed of a conductive material such as, but not limited to, Cu, Al, Ti, Zr, Hf, V, Ru, Co, Ni, Pd, Pt, W, Ag, Au or alloys thereof. The interconnect lines are also sometimes referred to in the art as traces, wires, lines, metal, or simply interconnect.

Referring now to FIG. 2B, a cross-sectional illustration of an interconnect layer 200 is shown, in accordance with an additional embodiment. In an embodiment, the interconnect layer 200 in FIG. 2B is substantially similar to the interconnect layer 200 in FIG. 2A, with the exception that a third interconnect 228 is included in the interconnect layer 200. In an embodiment, the third interconnect 228 may have a third height H₃. The third height H₃ may be less than the first height H₁ and greater than the second height H₃. The third interconnect 228 may be referred to as an intermediate interconnect. Accordingly, it is to be appreciated that interconnect layers 200 may comprise more than two interconnect heights. While three interconnect heights are shown in FIG. 2B, it is to be appreciated that any number of interconnect heights may be obtained. However, it is to be appreciated that increases to the number of interconnect heights will also result in increases to the processing costs.

Referring now to FIG. 2C, a cross-sectional illustration of an interconnect layer 200 is shown, in accordance with an additional embodiment. In an embodiment, the interconnect layer 200 is substantially similar to the interconnect layer 200 in FIG. 2A, with the exception that the ILD 220 comprises first portions 220_{A} and second portions 220_{B}. In an embodiment, the second portions 220_{B} may comprise air. That is, the interconnects 222/224 may be separated by air gaps. The use of air gaps further decreases the capacitance of the interconnects 222/224 and improves performance.

As shown in FIGS. 2A-2C, various options are available to the circuit designers to optimize the routing in the BEOL stack. Particularly, embodiments disclosed herein allow for the height of the interconnect to be chosen and/or whether the interconnects have air gaps. As will be described below, the selection of which type of interconnect and/or whether air gaps are included may be made at different levels of granularity (e.g., from the block level, down to the segment level).

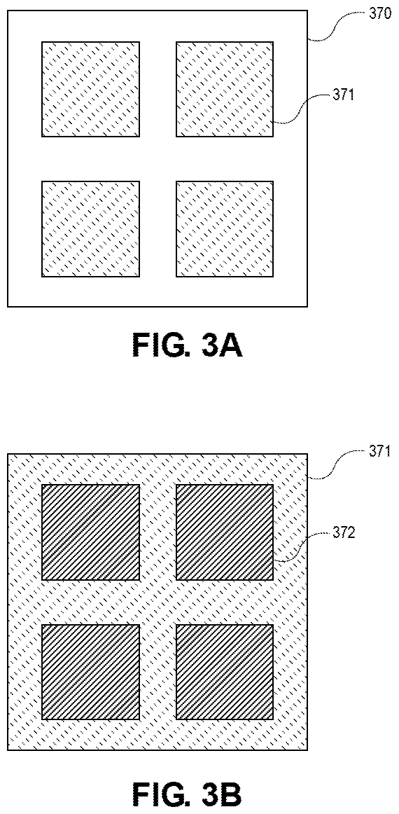

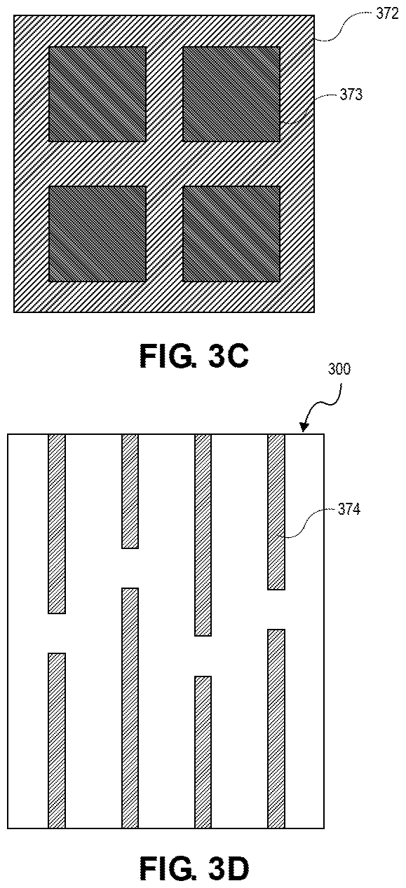

Referring now to FIG. 3A, a schematic view illustration of semiconductor die 370 is shown, in accordance with an embodiment. In an embodiment, the semiconductor die 370 may include a plurality of blocks 371. For example, the blocks 371 may include processing blocks, communication blocks, memory blocks, or the like. Since the blocks 371 perform different functions, they may need different optimizations. However, interconnect stacks are typically optimized for either high performance (e.g., low RC delay, with the interconnect in each higher layer of the interconnect stack becoming taller and larger pitch), or for maximum signal density at the expense of RC delay for lower frequency and power SoC designs. By supporting multi-height interconnects, both designs can be supported on the same manufacturing process. CPU or high frequency blocks (e.g., timing critical blocks 371) of a die 370 can use all tall interconnects (e.g., first interconnects 222 in FIG. 2A), while SoC or low frequency blocks 371 of a die 370 can use all short interconnects (e.g., second interconnects 224 in FIG. 2A). The use of tall interconnects allows for the resistance to be reduced, and therefore reduces delay along the interconnects. The use of short interconnects reduces the capacitance, and therefore reduces the power consumption.

Referring now to FIG. 3B, a schematic view illustration of a block 371 is shown, in accordance with an embodiment. In an embodiment, the block 371 may comprise a plurality of paths 372. In an embodiment, each path 372 may be optimized independently. That is, in some embodiments a block 371 may include first paths 372 with tall interconnects and second paths 372 with short interconnects.

Referring now to FIG. 3C, a schematic view illustration of a path 372 is shown, in accordance with an embodiment. In an embodiment, the path 372 may comprise a plurality of nets 373. In an embodiment, each net 373 may be optimized independently. That is, in some embodiments, a path 372 may comprise first nets 373 with tall interconnects and second nets 373 with short interconnects.

Referring now to FIG. 3D, a plan view illustration of a portion of an interconnect layer 300 is shown, in accordance with an embodiment. In an embodiment, the interconnect layer 300 includes a plurality of segments 374. The segments 374 may be part of a larger net 373. In an embodiment, each of the segments 374 may be optimized independently. That is, in some embodiments, a net 373 may comprise first segments 374 with tall interconnects and second segments 374 with short interconnects.

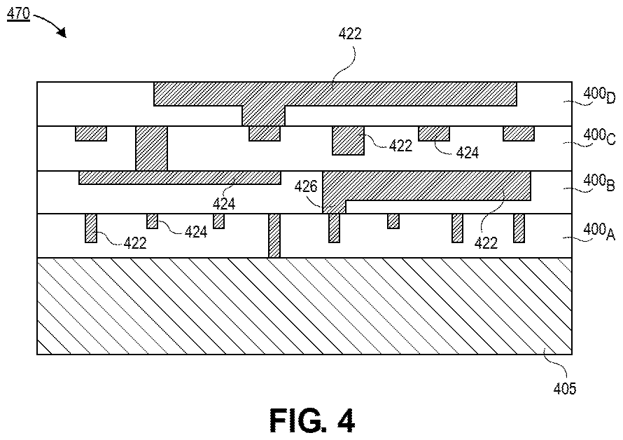

Referring now to FIG. 4, a cross-sectional illustration of a semiconductor die 470 is shown, in accordance with an embodiment. In an embodiment, the semiconductor die 470 may comprise a semiconductor substrate 405 and a plurality of interconnect layers 400 over the semiconductor substrate 405. The semiconductor substrate 405 may comprise a plurality of transistors or the like that are electrically coupled to interconnects 422/424 and vias 426 of the various interconnect layers 400.

In an embodiment, the underlying semiconductor substrate 405 represents a general workpiece object used to manufacture integrated circuits. The semiconductor substrate 405 often includes a wafer or other piece of silicon or another semiconductor material. Suitable semiconductor substrates include, but are not limited to, single crystal silicon, polycrystalline silicon and silicon on insulator (SOI), as well as similar substrates formed of other semiconductor materials, such as substrates including germanium, carbon, or group III-V materials. The semiconductor substrate 405, depending on the stage of manufacture, often includes transistors, integrated circuitry, and the like. The semiconductor substrate 405 may also include semiconductor materials, metals, dielectrics, dopants, and other materials commonly found in semiconductor substrates.

In the illustrated embodiment, four interconnect layers 400_{A-D} are shown. However, it is to be appreciated that there may be any number of interconnect layers 400 depending on the complexity of the semiconductor die 470. In an embodiment, one or more of the interconnect layers 400 may include interconnects with a non-uniform height. For example, interconnect layers 400_{A}, 400_{B}, and 400_{C} include first interconnects 422 and second interconnects 424. Furthermore, it is to be appreciated that not all interconnect layers 400 necessarily include non-uniform interconnect heights. For example, the fourth interconnect layer 400_{D} only includes first interconnects 422. In the illustrated embodiment, the uniform height interconnect layer 400_{D} is shown as the topmost layer. However, it is to be appreciated that a uniform height interconnect layer 400_{D} may also be positioned between interconnect layers 400 with non-uniform interconnect heights or below interconnect layers 400 with non-uniform interconnect heights.

Critical signals are typically promoted to higher interconnect layers to take advantage of faster RC delays. For example, in typical BEOL stacks layer M1 will have a first interconnect height and layer M2 will have a second interconnect height that is greater than the first height. Accordingly, promoting an interconnect up a layer will decrease delay. However, the higher interconnect layers typically have increased interconnect pitch, resulting in increased congestion. Accordingly, using multi-height interconnects (e.g., first interconnects 422 and second interconnects 424) within a single interconnect layer 400, signals that would otherwise need to be promoted to a higher layer may be kept at the lower layer by using a tall (first) interconnect 422. Embodiments may even allow for moving an interconnect to a lower layer in order to support higher signal density. Accordingly, the use of tall height interconnects (i.e., first interconnects 422) on these lower layers can retain the low RC delay while improving wiring congestion.

In the illustrated embodiment, each of the interconnect layers 400 are shown as being formed with a solid ILD layer. However, it is to be appreciated that one or more of the interconnect layers 400 may also comprise air gap dielectrics (similar to what is shown in FIG. 2C). The decision to use air gap dielectrics may be made on a layer by layer basis.

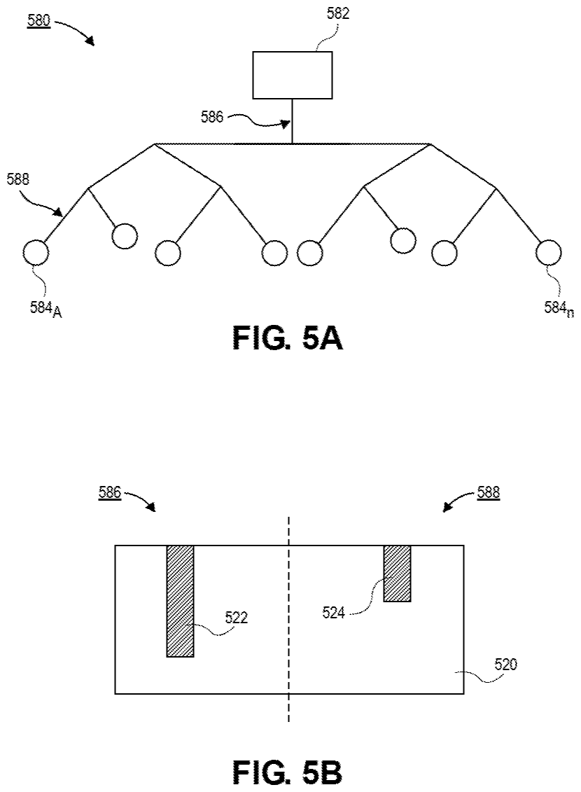

Referring now to FIGS. 5A and 5B, a schematic illustration and a cross-sectional illustration of a portion of a signal path 580 is shown, in accordance with an embodiment. In an embodiment, the path 580 may comprise a driving cell 582 and a plurality of load cells 584_{A-n}. Connecting from the driving cell 582 to all the load cells 584_{A-n} results in an interconnect that begins with a single segment 586 and splits into multiple interconnect segments 588 that connect to each load cell 584_{A-n}. Typical Elmore delay approximations of these structures include the resistance of each segment multiplied by the aggregate downstream capacitance seen by that segment. Such approximations recognize the importance of resistance in the segments proximate to the driving cell 582 (e.g., segment 586) that see nearly the total capacitive load. Changing such interconnect segments to tall segments will yield the largest delay improvement. Furthermore, retaining interconnect segments proximate to the load cells (e.g., segments 588) as short height interconnect reduces their capacitance, to save power.

Referring now to FIG. 5B, a cross-sectional illustration depicting the segment 586 (left) and the segment 588 (right) in an ILD 520 is shown, in accordance with an embodiment. As shown, the segment 586 may be implemented with a first interconnect 522, and the segment 588 may be implemented with a second interconnect 524. The first interconnect 522 may have a greater height than the second interconnect 524. Accordingly, the path 580 may be optimized for minimal delay while still having acceptable power consumption by using multi-height interconnects.

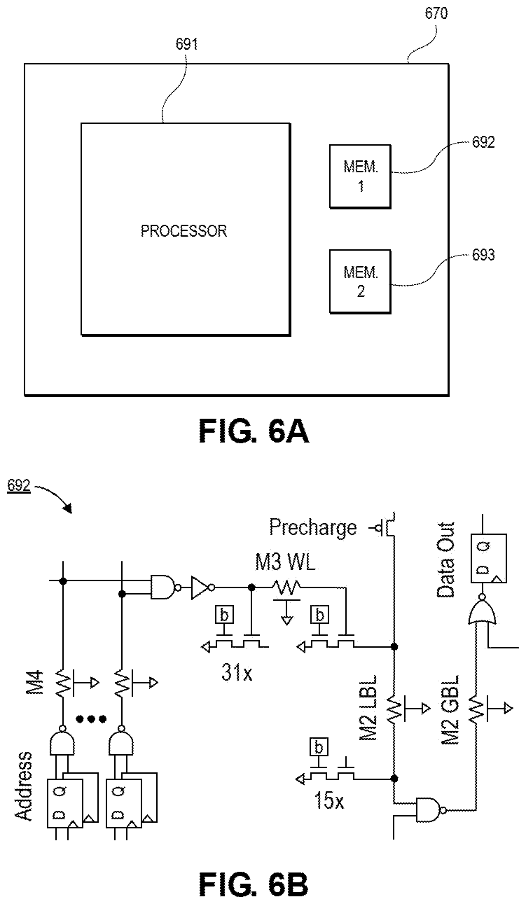

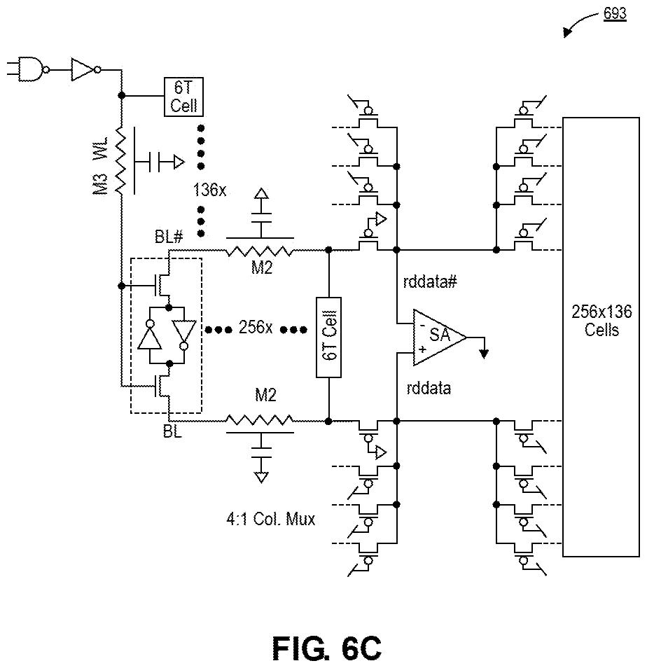

Referring now to FIG. 6A, a schematic view illustration of a semiconductor die 670 is shown, in accordance with an embodiment. In an embodiment, the semiconductor die 670 may comprise a first block 691, a second block 692, and a third block 693. In an embodiment, the first block 691 may be a processor block, or the like. The second block 692 and the third block 693 may be memory blocks or the like. In a particular embodiment, the second block 692 is a register file and the third block 693 is a static random access memory (SRAM). The second block 692 and the third block 693 may be electrically coupled to the first block 691 through the BEOL stack (not shown). In an embodiment, the BEOL stack also comprises interconnects between elements within a single block 691-693.

Referring now to FIG. 6B, a circuit diagram of the second block 692 is shown, in accordance with an embodiment. In the illustrated embodiment, the second block 692 is a register file. Register files are key local memory units that are predominantly used within processors, ASICs and SoCs to store and feed data for various execution units. Consequently, they are key power and performance limiters. The increased resistance and capacitance of on-chip interconnects directly degrade performance and power for these units.

A typical register file 692 critical delay path includes word lines (WL) to turn on the access transistor for a particular entry, followed by bit lines (BL) to read the value stored in that entry. These incur long interconnects in the BEOL stack, which constitute a large part of the register file delay and energy consumption. FIG. 6B illustrates this critical path for an exemplary 64-entry×32b register file with word lines in metal 3 (M3 WL), while local and global bit lines are routed in metal 2 (M2 LBL and M2 GBL). While a 64-entry×32b register file is shown, it is to be appreciated that similar optimizations available through the use of multi-height interconnects and air gap dielectrics may be implemented with a register file of any size and/or configuration.

According to embodiments disclosed herein, the word lines WL and the bit lines LBL and GBL may be implemented with different interconnect heights, and/or with or without air gap dielectrics. This allows for many different configurations that are available for meeting different performance metrics. In a first modification, the addition of an air gap dielectric around the interconnects for the word lines WL and the bit lines LBL and GBL result in an approximately 5% reduction in the overall delay. Changing all interconnects (e.g., all word lines WL and all bit lines LBL and GBL) to taller height wires with a multi-height interconnect process results in a further 5% reduction in the overall delay.

It has been found that all of the contributions to delay from the various circuit components are comparable to each other. That is, increasing the height of the word line WL will provide substantially the same reduction in delay that is provided by increasing the height of the local bit line LBL or the global bit line GBL. However, it has been shown that in terms of energy consumption, the bit line (LBL and GBL) switching energy dominates. Accordingly, implementing the bit lines LBL and GBL with tall interconnects has a significant power consumption penalty. As such, an optimized multi-height option may include the use of short interconnects for bit lines (LBL and/or GBL) to obtain an energy advantage from the lower capacitance of these interconnects, while still maintaining the delay advantage with lower resistance tall interconnects for the word lines WL. Overall, it has been shown that a register file 692 with such tall/short interconnect optimizations and air gap dielectric results in an approximately 15% delay reduction and approximately 5% energy reduction compared to the baseline design.

Referring now to FIG. 6C, a circuit diagram of the third block 693 is shown, in accordance with an embodiment. In the illustrated embodiment, the second block 693 is an SRAM. SRAMs are used for storing the largest amount of data on-chip due to their high density. They are typically very large and can limit processor clock frequency. SRAM clock period is dominated by bit line delay, which is determined by the number of bit cells on a single bit line and the RC characteristic of the bit line interconnects. Interconnect RC delays degrade with process scaling and limit SRAM performance scalability.

Multi-height interconnects and air gap dielectrics enable SRAM optimizations based on lower RC (tall interconnects) vs. lower capacitance (short interconnects). Rather than use all tall or all short interconnects in a single layer, the optimized SRAM uses tall interconnects only on word lines and short interconnects on bit lines to minimize delay. In addition to wire height optimization, selective use of air gap dielectrics only on the bit line metal layer improves SRAM performance, while minimizing extra processing cost.

A typical SRAM critical delay path includes word lines (WL) to turn on the access transistors for a particular entry, followed by bit lines (BL and BL #) to read the value stored in that entry, along with any column multiplexing logic. The differential bit lines BL and BL # switch slowly, and a sense-amplifier (SA) is used to read a small differential voltage to enable many cells to be shared on a bit line while meeting CPU clock period. In FIG. 6C the SRAM 693 is a 68b×3584-entry SRAM. However, similar relationships and optimizations may be found for SRAMs of any size or configuration.

The RC characteristics of the bit line BL and BL # interconnects dominate the delay. In a multi-height interconnect process most logic and register file critical paths would favor using the tall wires due to their lower resistance. However, in an SRAM, it has been shown that the bit line delays are dominated by interconnect capacitance (i.e., most of the resistance is in the SRAM device rather than bit line interconnects). Accordingly, increasing the height of the bit lines may not provide a significant improvement in delay. Therefore, embodiments disclosed herein include short interconnects on the bit lines BL and BL # in order to provide delay improvements. For example, using short interconnects for the bit lines BL and BL # may result in delay reductions of up to approximately 10%. Adding air gap dielectrics to the metal layer that the bit lines are in (e.g., M2 in FIG. 6C) results in up to an additional 15% delay reduction since the air gap dielectric further reduces capacitance. In an embodiment, the word line WL may be in one or more metal layers. For example, the word line WL is shown as being in M3 in FIG. 6C. The word line WL may include tall interconnects in order to provide reduced resistance and improved delay. Accordingly, embodiments may include an SRAM 693 with word lines WL that are implemented as tall interconnects and bit lines BL and BL # that are implemented as short interconnects. Embodiments may also include air gap dielectric architectures in any number of the metal layers.

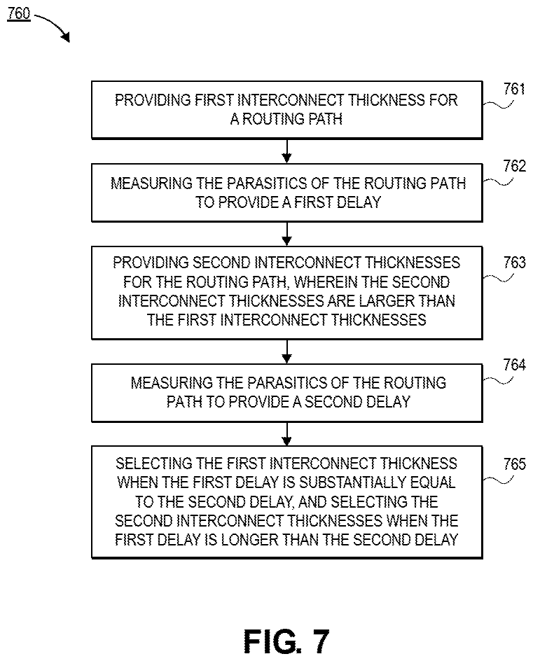

Referring now to FIG. 7, a process flow diagram that illustrates a process 760 for optimizing the routing architecture of a semiconductor die is shown, in accordance with an embodiment. Process 760 may begin with operation 761 which includes providing first interconnect thicknesses for a routing path. Process 760 may then continue with operation 762 which includes measuring the parasitics of the routing path to provide a first delay. In an embodiment, process 760 may then continue with operation 763 which includes providing second interconnect thicknesses for the routing path. In an embodiment, the second thicknesses may be larger than the first thicknesses. Embodiments may then continue with operation 764 which includes measuring the parasitics of the routing path to provide a second delay. Embodiments may then include operation 765 which comprises selecting the first interconnect thickness when the first delay is substantially equal to the second delay, and selecting the second interconnect thickness when the first delay is longer than the second delay. Embodiments may also reverse the order of testing. That is, all of the interconnects may first be tall interconnects, followed by testing all short interconnects. In an embodiment, the optimization of the routing architecture in process 760 may be implemented at the block level, the path level, the net level, and/or the segment level. In an embodiment, the process 760 may be implemented in whole or in part by an automatic-place-and-route (APR) algorithm, or any other suitable software.

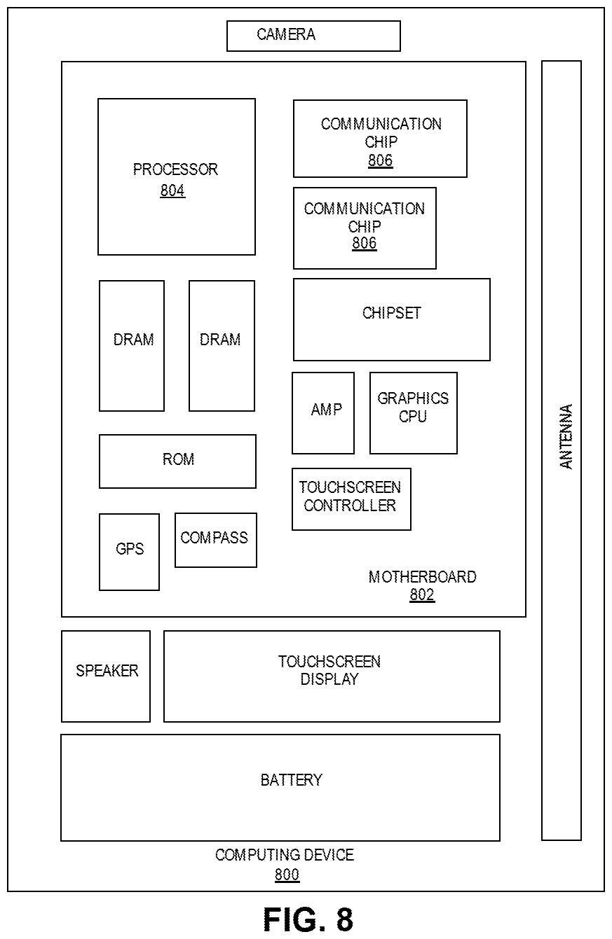

FIG. 8 illustrates a computing device 800 in accordance with one implementation of an embodiment of the disclosure. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

Depending on its applications, computing device 800 may include other components that may or may not be physically and electrically coupled to the board 802. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In an embodiment, the integrated circuit die of the processor may comprise interconnect layers that have interconnects with non-uniform heights, as described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In an embodiment, the integrated circuit die of the communication chip 806 may comprise interconnect layers that have interconnects with non-uniform heights, as described herein.

In further implementations, another component housed within the computing device 800 may comprise interconnect layers that have interconnects with non-uniform heights, as described herein.

In various implementations, the computing device 800 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 800 may be any other electronic device that processes data.

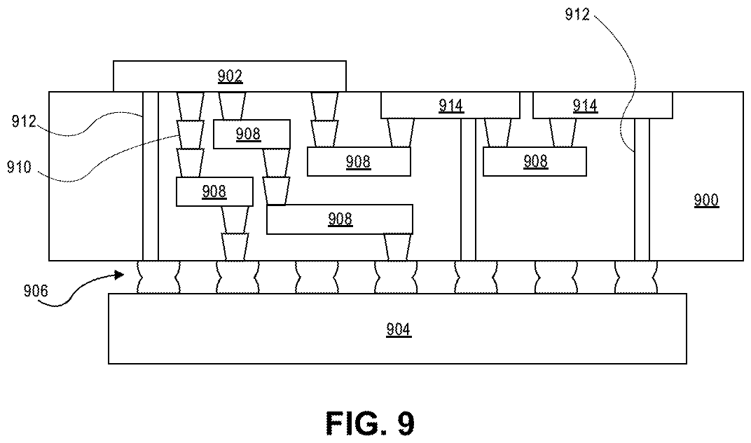

FIG. 9 illustrates an interposer 900 that includes one or more embodiments of the disclosure. The interposer 900 is an intervening substrate used to bridge a first substrate 902 to a second substrate 904. The first substrate 902 may be, for instance, an integrated circuit die. The second substrate 904 may be, for instance, a memory module, a computer motherboard, or another integrated circuit die. In an embodiment, one of both of the first substrate 902 and the second substrate 904 may comprise an overlay target with a first interference pattern, a second interference pattern, and a pattern recognition feature, or be fabricated using such an overlay target, in accordance with embodiments described herein. Generally, the purpose of an interposer 900 is to spread a connection to a wider pitch or to reroute a connection to a different connection. For example, an interposer 900 may couple an integrated circuit die to a ball grid array (BGA) 906 that can subsequently be coupled to the second substrate 904. In some embodiments, the first and second substrates 902/904 are attached to opposing sides of the interposer 900. In other embodiments, the first and second substrates 902/904 are attached to the same side of the interposer 900. And in further embodiments, three or more substrates are interconnected by way of the interposer 900.

The interposer 900 may be formed of an epoxy resin, a fiberglass-reinforced epoxy resin, a ceramic material, or a polymer material such as polyimide. In further implementations, the interposer 900 may be formed of alternate rigid or flexible materials that may include the same materials described above for use in a semiconductor substrate, such as silicon, germanium, and other group III-V and group IV materials

The interposer 900 may include metal interconnects 908 and vias 910, including but not limited to through-silicon vias (TSVs) 912. The interposer 900 may further include embedded devices 914, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 900. In accordance with embodiments of the disclosure, apparatuses or processes disclosed herein may be used in the fabrication of interposer 900.

Thus, embodiments of the present disclosure may comprise interconnect layers that have interconnects with non-uniform heights, and the resulting structures.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: a semiconductor device, comprising: a semiconductor substrate; and a back end of line (BEOL) stack over the semiconductor substrate, wherein the BEOL stack comprises: first interconnects and second interconnects in an interconnect layer of the BEOL stack, wherein the first interconnects have a first height and the second interconnects have a second height that is different than the first height.

Example 2: the semiconductor device of Example 1, further comprising: an air gap dielectric surrounding the first interconnects and/or the second interconnects.

Example 3: the semiconductor device of Example 1 or Example 2, wherein the semiconductor substrate comprises a first processing block and a second processing block.

Example 4: the semiconductor device of Example 3, wherein an interconnect scheme for the first processing block comprises first interconnects, and wherein an interconnect scheme for the second processing block comprises second interconnects.

Example 5: the semiconductor device of Example 3 or Example 4, wherein the first processing block comprises a first path and a second path.

Example 6: the semiconductor device of Example 5, wherein the first path comprises first interconnects, and wherein the second path comprises second interconnects.

Example 7: the semiconductor device of Example 5 or Example 6, wherein the first path comprises a first net and a second net.

Example 8: the semiconductor device of Example 7, wherein the first net comprises first interconnects, and wherein the second net comprises second interconnects.

Example 9: the semiconductor device of Example 7 or Example 8, wherein the first net comprises a first segment and a second segment.

Example 10: the semiconductor device of Example 9, wherein the first segment comprises first interconnects, and wherein the second segment comprises second interconnects.

Example 11: the semiconductor device of Examples 1-10, further comprising: a signal path comprising: a drive cell; and a plurality of load cells, wherein each load cell is electrically coupled to the drive cell by interconnects in the BEOL stack.

Example 12: the semiconductor device of Example 11, wherein a first portion of the signal path proximate to the drive cell is one of the first interconnects, and wherein second portions of the signal path proximate to the plurality of load cells are ones of the second interconnects.

Example 13: the semiconductor device of Examples 1-12, wherein the BEOL stack comprises a plurality of interconnect layers that each comprise first interconnects and second interconnects.

Example 14: the semiconductor device of Examples 1-13, further comprising: third interconnects in the interconnect layer of the BEOL stack, wherein the third interconnects have a third height that is between the first height and the second height.

Example 15: the semiconductor device, comprising: a semiconductor substrate, comprising: a processor block; and a memory block coupled to the processor block; and a back end of line (BEOL) stack over the semiconductor substrate, wherein the BEOL stack provides conductive coupling between the processor block and the memory block, wherein the BEOL stack comprises a plurality of interconnect layers, wherein one or more of the plurality of interconnect layer comprise: first interconnects having a first height; and second interconnects having a second height that is less than the first height.

Example 16: the semiconductor device of Example 15, wherein the memory block is a register file and comprises word lines and bit lines implemented in the BEOL stack.

Example 17: the semiconductor device of Example 16, wherein the word lines are implemented with first interconnects.

Example 18: the semiconductor device of Example 17, wherein the bit lines are implemented with second interconnects.

Example 19: the semiconductor device of Examples 16-18, further comprising air-gap dielectrics, wherein the air-gap dielectrics are around the word lines and the bit lines, or wherein the air-gap dielectrics are only around the bit lines.

Example 20: the semiconductor device of Examples 15-19, wherein the memory block is static random access memory (SRAM), and comprises word lines and bit lines implemented in the BEOL stack.

Example 21: the semiconductor device of Example 20, wherein the bit lines are implemented with second interconnects.

Example 22: the semiconductor device of Example 21, further comprising: an air gap dielectric around the bit lines, and wherein the word lines are implemented with first interconnects.

Example 23: an electronic system, comprising: a board; and an electronic package coupled to the board, wherein the electronic package comprises a semiconductor die, and wherein the semiconductor die comprises: a semiconductor substrate; and first interconnects and second interconnects in an interconnect layer over the semiconductor substrate, wherein the first interconnects have a first height and the second interconnects have a second height that is different than the first height.

Example 24: the electronic system of Example 23, wherein the semiconductor substrate comprises: a processor block; and a memory block that is electrically coupled to the processor block by one or more interconnects in the interconnect layer.

Example 25: the electronic system of Example 24, wherein the memory block is a register file or a static random access memory (SRAM).

What is claimed is:

1. A semiconductor device, comprising:
a semiconductor substrate; and
a back end of line (BEOL) stack over the semiconductor substrate, wherein the BEOL stack comprises:
first interconnects and second interconnects in an interconnect layer of the BEOL stack, wherein the first interconnects have a first height and the second interconnects have a second height that is different than the first height.

2. The semiconductor device of claim 1, further comprising:
an air gap dielectric surrounding the first interconnects and/or the second interconnects.

3. The semiconductor device of claim 1, wherein the semiconductor substrate comprises a first processing block and a second processing block.

4. The semiconductor device of claim 3, wherein an interconnect scheme for the first processing block comprises first interconnects, and wherein an interconnect scheme for the second processing block comprises second interconnects.

5. The semiconductor device of claim 3, wherein the first processing block comprises a first path and a second path.

6. The semiconductor device of claim 5, wherein the first path comprises first interconnects, and wherein the second path comprises second interconnects.

7. The semiconductor device of claim 5, wherein the first path comprises a first net and a second net.

8. The semiconductor device of claim 7, wherein the first net comprises first interconnects, and wherein the second net comprises second interconnects.

9. The semiconductor device of claim 7, wherein the first net comprises a first segment and a second segment.

10. The semiconductor device of claim 9, wherein the first segment comprises first interconnects, and wherein the second segment comprises second interconnects.

11. The semiconductor device of claim 1, further comprising:
a signal path comprising:
a drive cell; and
a plurality of load cells, wherein each load cell is electrically coupled to the drive cell by interconnects in the BEOL stack.

12. The semiconductor device of claim 11, wherein a first portion of the signal path proximate to the drive cell is one of the first interconnects, and wherein second portions of the signal path proximate to the plurality of load cells are ones of the second interconnects.

13. The semiconductor device of claim 1, wherein the BEOL stack comprises a plurality of interconnect layers that each comprise first interconnects and second interconnects.

14. The semiconductor device of claim 1, further comprising:
third interconnects in the interconnect layer of the BEOL stack, wherein the third interconnects have a third height that is between the first height and the second height.

15. A semiconductor device, comprising:
a semiconductor substrate, comprising:
a processor block; and
a memory block coupled to the processor block; and
a back end of line (BEOL) stack over the semiconductor substrate, wherein the BEOL stack provides conductive coupling between the processor block and the memory block, wherein the BEOL stack comprises a plurality of interconnect layers, wherein one or more of the plurality of interconnect layer comprise:
first interconnects having a first height; and
second interconnects having a second height that is less than the first height.

16. The semiconductor device of claim 15, wherein the memory block is a register file and comprises word lines and bit lines implemented in the BEOL stack.

17. The semiconductor device of claim 16, wherein the word lines are implemented with first interconnects.

18. The semiconductor device of claim 17, wherein the bit lines are implemented with second interconnects.

19. The semiconductor device of claim 16, further comprising air-gap dielectrics, wherein the air-gap dielectrics are around the word lines and the bit lines, or wherein the air-gap dielectrics are only around the bit lines.

20. The semiconductor device of claim 15, wherein the memory block is static random access memory (SRAM), and comprises word lines and bit lines implemented in the BEOL stack.

21. The semiconductor device of claim 20, wherein the bit lines are implemented with second interconnects.

22. The semiconductor device of claim 21, further comprising:
an air gap dielectric around the bit lines, and wherein the word lines are implemented with first interconnects.

23. An electronic system, comprising:
a board; and
an electronic package coupled to the board, wherein the electronic package comprises a semiconductor die, and wherein the semiconductor die comprises:
a semiconductor substrate; and
first interconnects and second interconnects in an interconnect layer over the semiconductor substrate, wherein the first interconnects have a first height and the second interconnects have a second height that is different than the first height.

24. The electronic system of claim 23, wherein the semiconductor substrate comprises:
a processor block; and
a memory block that is electrically coupled to the processor block by one or more interconnects in the interconnect layer.

25. The electronic system of claim 24, wherein the memory block is a register file or a static random access memory (SRAM).
